(19) United States
(12) Patent Application Publication
(10) Pub. No.: US 2002/0075058 A1
(43) Pub. Date: Jun. 20, 2002

(54) Apparatus for low-power, high performance, and cycle accurate test simulation

(76) Inventors: Chi-Yi Hwang, Kaohsiung Hsien (TW); Shao-I Chen, Taipei (TW); Cheng-I Huang, Taoyuan Hsien (TW); Kun-Cheng Wu, Hsinchu (TW)

Correspondence Address: J.C. Patents, Inc., 4 Venture, Suite 250, Irvine, CA, 92618, US

(21) Appl. No.: 09/741,609

(22) Filed: Dec. 19, 2000

(51) Int. Cl. H03K 17/62

(52) U.S. Cl. 327/407

(57) ABSTRACT

A method for preventing redundant events from toggling the core logic during scan data shifting mode is provided. A logic element is controlled by SEL. During scan data shifting mode, no toggled data will interfere with the core logic because the logic element is shut off. Only the scan path (SI-SO-SI) continues toggling. Therefore, redundant events are prevented from toggling the core logic. Therefore the simulation time is reduced and the verification flow is sped up. Additionally, the power consumption during testing is significantly reduced.

### BACKGROUND OF THE INVENTION

1. Field of Invention

The present invention relates to a multiplex scan cell, and more particularly, to a multiplex scan cell that prevents triggering of redundant events in core logic during scan data shifting mode.

2. Description of Related Art

Digital integrated circuits are made up of complex networks for performing numerous logical operations on data. The complexity of these networks makes testing the integrated circuit difficult.

Therefore, circuits inside the integrated circuit are divided into networks and scanable memory elements. The memory elements such as flip-flops are designed to be reconfigurable from their original operating configuration in order to facilitate testing of the integrated circuit.

Various techniques are available for testing integrated circuits. One technique utilizes latches or flip-flops configured into a serial shift-register chain to shift test signals into a device and pass responses back out for analysis.

Since the flip-flops are reconfigurable, during testing the flip-flops can be configured into their original operating configuration connecting them with the networks and circuits required to perform the logical operations on the test data. Then the flip-flops can be changed back to the scan configuration in order to shift the data out of the scan chains as test response data for analysis.

Refer to FIG. 1, which shows a conventional multiplex (MUX) scan cell. The basic module of this type of scan test is a multiplexer 50 driving a flip-flop 60. The multiplexer 50 switches data between scan in test data 20 and system data 10, representing normal or system information. A select control line (SEL) 30 controls the switching. On the first scan cell, the serial input connects to the primary input (SI). On intermediate cells, the serial input usually comes from the previous cell's output. On the last cell, the output is scan out (SO) 70. Selecting the test or serial mode creates a complete serial shift path from input to output.

In scan data shifting mode, SEL 30 is a logic 1. During scan data shifting mode, the scan output (SO) 70 data does not pertain to the core logic 90. However, the scan output data continues toggling the core logic 90 and creating events. These redundant events cause the complexity of simulation to increase which results in a longer simulation time than necessary. Also, additional power is consumed during testing because of these unnecessary events.

### SUMMARY OF THE INVENTION

Therefore, in order to overcome the disadvantages of the conventional apparatus, the invention provides a method for preventing redundant events from triggering the core logic during scan data shifting mode.

Refer to FIG. 2, which shows a block diagram of a MUX scan cell according to an embodiment of the present invention. The MUX scan cell comprises a multiplexer 150, a flip-flop 160, and a logic element 180. The multiplexer 150 selects between test data 120 and system data 110.

The logic element 180 is controlled by SEL 130. During scan data shifting mode SEL 130 is a logic 1, so therefore, no toggled data will interfere with the core logic 190 because the logic element 180 is shut off. Only the scan path (SI-SO-SI) 170 continues toggling. Therefore, redundant events are prevented from toggling the core logic 190.

As described previously, in the conventional MUX scan cell, too many redundant events are triggered during test data shifting mode. These redundant events result in untolerably long simulation times. Additionally, these redundant events consume excess power during testing.

In contrast, the MUX scan cell of an embodiment of the present invention can prevent the triggering of redundant events during scan data shifting mode. This results in reduced simulation time and speeds up the verification flow. Also, the power consumption is reduced during testing.

It is to be understood that both the foregoing general description and the following detailed description are exemplary, and are intended to provide further explanation of the invention as claimed.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention. In the drawings,

FIG. 1 shows a conventional MUX scan cell;

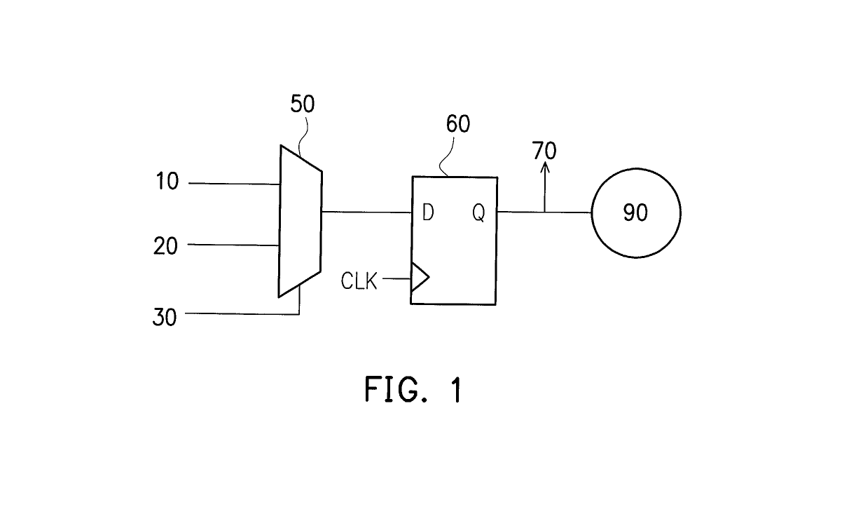

FIG. 2 shows a block diagram of a MUX scan cell according to an embodiment of the present invention;

FIG. 3 shows a circuit schematic for a MUX scan cell according to an embodiment of the present invention; and

FIG. 4 shows a circuit schematic for a MUX scan cell according to an embodiment of the present invention.

### DESCRIPTION OF THE PREFERRED EMBODIMENTS

In order to overcome the shortcomings of the conventional MUX scan cell, an improved MUX scan cell is provided which prevents the triggering of redundant events in the core logic during scan data shifting mode.

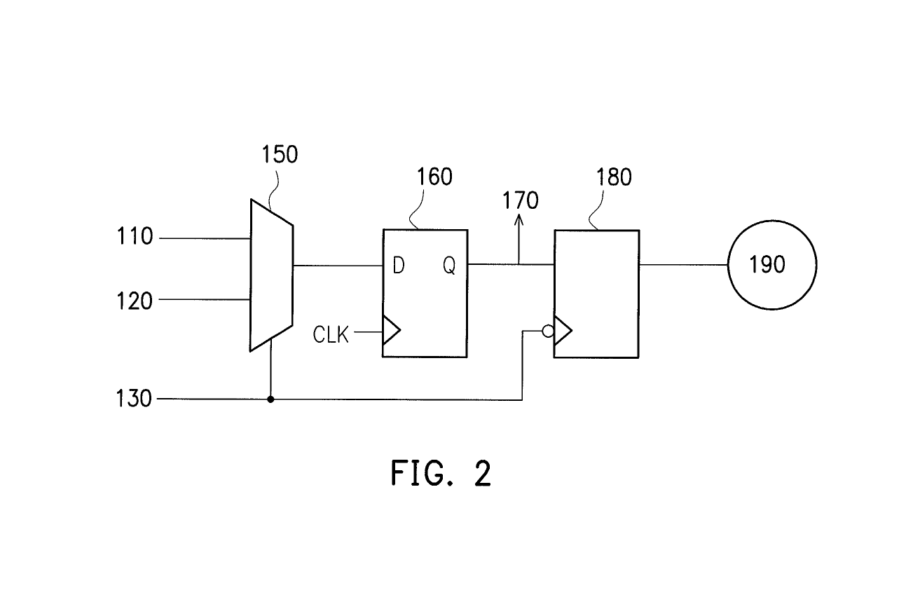

Refer again to FIG. 2, which shows a block diagram of a MUX scan cell according to an embodiment of the present invention. The MUX scan cell comprises a multiplexer 150, a flip-flop 160, and a logic element 180. The multiplexer 150 selects between test data 120 and system data 110.

The logic element 180 can be any logic device or group of devices that can provide a means of allow data to pass through the device or devices or prevent data from flowing through the device or devices, based upon the status of a select signal. The logic element 180 is controlled by SEL 130. During scan data shifting mode SEL 130 is a logic 1 so, therefore, no toggled data will interfere with the core logic 190 because the logic element 180 is turned off. Only the scan path (SI-SO-SI) 170 continues toggling. Therefore, redundant events are prevented from toggling the core logic 190.

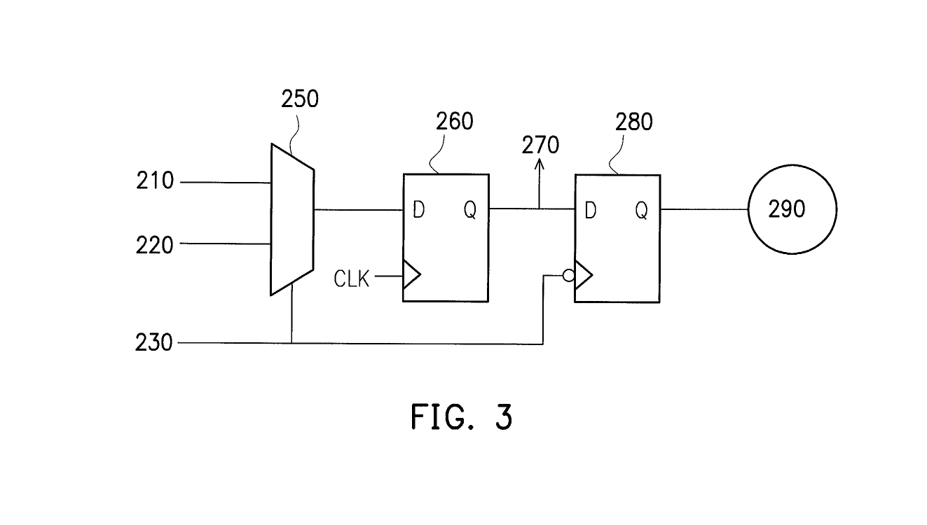

Refer to FIG. 3, which shows a circuit schematic for a MUX scan cell according to another embodiment of the present invention. The MUX scan cell comprises a multiplexer 250, a flip-flop 260, and a latch 280. The multiplexer 250 selects between test data 220 and system data 210.

The latch 280 is controlled by SEL 230. During scan data shifting mode SEL 230 is a logic 1 so, therefore, no toggled data will interfere with the core logic 290 because the latch 280 is shut off. Only the scan path (SI-SO-SI) 270 continues toggling. Therefore, redundant events are prevented from toggling the core logic 290.

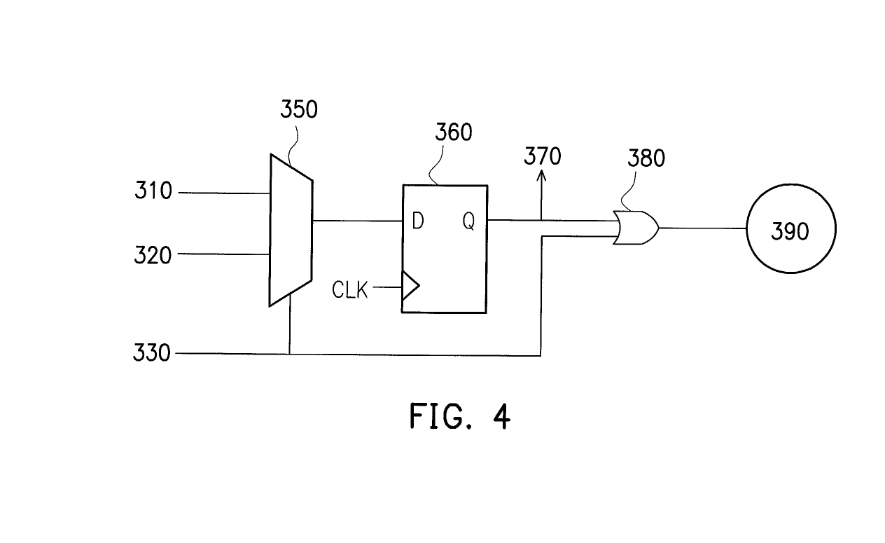

Refer to FIG. 4, which shows a circuit schematic for a MUX scan cell according to an embodiment of the present invention. The MUX scan cell comprises a multiplexer 350, a flip-flop 360, and an OR gate 380. The multiplexer 350 selects between test data 320 and system data 310.

The data output of the OR gate 380 is controlled by SEL 330. During scan data shifting mode SEL 330 is a logic 1 so, therefore, no toggled data will interfere with the core logic 390 because the data output of the OR gate 380 doesn't change. Only the scan path (SI-SO-SI) 370 continues toggling. Therefore, redundant events are prevented from toggling the core logic 390. During normal operation SEL 330 is low so data passes through the OR gate 380 to the core logic 390.

It will be apparent to those skilled in the art that various modifications and variations can be made to the structure of the present invention without departing from the scope or spirit of the invention. In view of the foregoing, it is intended that the present invention cover modifications and variations of this invention provided they fall within the scope of the following claims and their equivalents.

What is claimed is:

1. An apparatus for preventing triggering of redundant events in core logic during scan data mode comprising:
a multiplexer for selecting data between system data and test data and providing selected data as a data output;
a flip-flop for storing the data output from the multiplexer; and
a latch for providing data stored in the flip-flop to core logic if the data is system data and for preventing data from reaching core logic if data is test data.

2. The apparatus for preventing triggering of redundant events of claim 1, wherein the multiplexer further comprises a select signal indicating if data is system data or test data.

3. An apparatus for preventing triggering of redundant events in core logic during scan data mode comprising:
a multiplexer for selecting data between system data and test data and providing selected data as a data output;
a flip-flop for storing the data output from the multiplexer; and
an OR gate for providing data stored in the flip-flop to core logic if the data is system data and for preventing data from reaching core logic if data is test data.

4. The apparatus for preventing triggering of redundant events of claim 3, wherein the multiplexer further comprises a select signal indicating if data is system data or test data.

5. An apparatus for preventing triggering of redundant events in core logic during scan data mode comprising:
a multiplexer for selecting data between system data and test data and providing selected data as a data output;
a flip-flop for storing the data output from the multiplexer; and
a logic element for providing data stored in the flip-flop to core logic if the data is system data and for preventing data from reaching core logic if data is test data.

6. The apparatus for preventing triggering of redundant events of claim 3, wherein the multiplexer further comprises a select signal indicating if data is system data or test data.
